(19) United States
(12) Patent Application Publication
(10) Pub. No.: US 2025/0130491 A1
(43) Pub. Date: Apr. 24, 2025

(54) RESIST COMPOSITION FOR PHOTOLITHOGRAPHY AND METHOD FOR MANUFACTURING SEMICONDUCTOR DEVICES USING THE SAME

(71) Applicant: Inha University Research and Business Foundation, Incheon (KR)

(72) Inventors: Jinkyun LEE, Incheon (KR); Yejin KU, Incheon (KR); Min Seung KIM, Incheon (KR)

(73) Assignee: Inha University Research and Business Foundation, Incheon (KR)

(21) Appl. No.: 18/917,232

(22) Filed: Oct. 16, 2024

(30) Foreign Application Priority Data
Oct. 20, 2023 (KR) 10-2023-0140821
Jul. 30, 2024 (KR) 10-2024-0101083

(51) Int. Cl. G03F 7/004; G03F 7/027; G03F 7/20; G03F 7/40

(52) U.S. Cl. CPC G03F 7/0043; G03F 7/027; G03F 7/2004; G03F 7/40

(57) ABSTRACT

Provided is a resist composition for photolithography and a method for manufacturing a semiconductor device using the same. The resist composition includes a metal-oxo cluster having a counter anion, the counter anion is a carboxylate anion having a substituted or unsubstituted unsaturated hydrocarbon group having 2 to 20 carbons, or a sulfonate anion having a substituted or unsubstituted unsaturated hydrocarbon group having 2 to 20 carbons.

### CROSS-REFERENCE TO RELATED APPLICATIONS

This U.S. non-provisional patent application claims priority under 35 U.S.C. § 119 of Korean Patent Application Nos. 10-2023-0140821, filed on Oct. 20, 2023, and 10-2024-0101083, filed on Jul. 30, 2024, the entire contents of which are hereby incorporated by reference.

### BACKGROUND

This research was conducted with the support of Samsung Science & Technology Foundation (Project No. SRFC-TA1703-05, SRFC-TA1703-51)

The present disclosure herein relates to a resist composition for photolithography, and a method for manufacturing a semiconductor device using the same.

Photolithography may include an exposure process and a developing process. Performing the exposure process may include inducing a chemical structural change of a resist film by irradiating light with a specific wavelength onto the resist film. Performing a developing process may include selectively removing an exposed part or unexposed part using a solubility difference between the exposed part and the unexposed part of the resist film.

With the high integration and miniaturization of semiconductor devices in recent years, the linewidth of patterns within the semiconductor devices has been decreasing. For forming fine patterns, various research, which improves resolution and sensitivity of the resist pattern formed by the photolithography and also suppresses collapse of the resist pattern, has been being conducted. In addition, demands for a resist pattern having excellent etch resistance against an etching process have been increased.

### SUMMARY

The present disclosure provides a resist composition capable of improving resolution and sensitivity of a photoresist pattern and capable of increasing etch resistance of the photoresist pattern.

The present disclosure also provides a method for manufacturing a semiconductor device using the above-described resist composition.

Tasks desired to solve in the present disclosure are not limited to the tasks described hitherto, other tasks not mentioned can be clearly understood to those skilled in the art from the following description.

In an embodiment of the inventive concept, a resist composition for photolithography is provided, and the resist composition may include a metal-oxo cluster represented by Formula 1.

[(R-M)₁₂O₁₄(OH)₆]²⁺[Rx⁻]₂ [Formula 1]
M is a metal, and is at least one selected from the group consisting of tin (Sn), zinc (Zn), lithium (Li), sodium (Na), potassium (K), beryllium (Be), magnesium (Mg), calcium (Ca), barium (Ba), aluminum (Al), silicon (Si), cadmium (Cd), mercury (Hg), chromium (Cr), iron (Fe), cobalt (Co), nickel (Ni), copper (Cu), germanium (Ge), palladium (Pd), platinum (Pt), lead (Pb), strontium (Sr), and manganese (Mn),
R is an alkyl group having 1 to 20 carbons, or a halogenated alkyl group having 1 to 20 carbons,

Rx⁻ is a counter anion, and is a carboxylate anion having a substituted or unsubstituted unsaturated hydrocarbon group having 2 to 20 carbons, or a sulfonate anion having a substituted or unsubstituted unsaturated hydrocarbon group having 2 to 20 carbons.

In an embodiment of the inventive concept, a method for manufacturing a semiconductor device is provided, and the method may include forming an etching target layer on a substrate, forming a photoresist film on the etching target layer, and performing an exposure process on the photoresist film. The exposure process may be performed using EUV or electron beam. The photoresist film may include a metal-oxo cluster having a counter anion, and the counter anion is a carboxylate anion having a substituted or unsubstituted unsaturated hydrocarbon group having 2 to 20 carbons, or a sulfonate anion having a substituted or unsubstituted unsaturated hydrocarbon group having 2 to 20 carbons.

In an embodiment of the inventive concept, a method for manufacturing a semiconductor device is provided, and the method may include forming an etching target layer on a substrate, forming a photoresist film on the etching target layer, and performing an exposure process on the photoresist film. The photoresist film may include a metal-oxo cluster represented by Formula 1.

### BRIEF DESCRIPTION OF THE FIGURES

The accompanying drawings are included to provide a further understanding of the inventive concept, and are incorporated in and constitute a part of this specification. The drawings illustrate embodiments of the inventive concept and, together withe description, serve to explain principles of the inventive concept. In the drawings:

FIG. 1 is a view illustrating Fourier transform infrared (FTIR) spectra of BTOC synthesized according to Example 1 and 2PBTOC synthesized according to Example 2;

FIG. 2 is a view illustrating a ¹H NMR spectrum of 2PBTOC synthesized according to Example 2;

FIG. 3 is a view illustrating FTIR spectra of BTOC synthesized according to Example 1 and TPBTOC synthesized according to Example 3;

FIG. 4 is a view illustrating a ¹H NMR spectrum of TPBTOC synthesized according to Example 3;

FIG. 5 is a view illustrating FTIR spectra of BTOC synthesized according to Example 1 and MPBTOC synthesized according to Example 4;

FIG. 6 is a view illustrating a ¹H NMR spectrum of MPBTOC synthesized according to Example 4;

FIG. 7 is a view illustrating FTIR spectra of BTOC synthesized according to Example 1 and PBTOC synthesized according to Example 5;

FIG. 8 is a view illustrating a ¹H NMR spectrum of PBTOC synthesized according to Example 5;

FIG. 9 is a view illustrating a FTIR spectrum of 2PTOC6 formed through an anionic substitution reaction of TOC6, according to Example 6;

FIG. 10 is a view illustrating a ¹H NMR spectrum of 2PTOC6 synthesized according to Example 6;

FIG. 11 is a view illustrating a ¹⁹F NMR spectrum of 2PTOC6 synthesized according to Example 6;

FIG. 12 is a view illustrating a FTIR spectrum of PTOC6 formed through an anionic substitution reaction of TOC6, according to Example 7;

FIG. 13 is a view illustrating a ¹H NMR spectrum of PTOC6 synthesized according to Example 7;

FIG. 14 is a view illustrating a ¹⁹F NMR spectrum of PTOC6 synthesized according to Example 7;

FIG. 15 is a view showing evaluation results of changes in solubility of a resist film for an electron beam lithography process according to Example 8;

FIG. 16 is scanning electron microscope images of a negative tone resist pattern formed by a lithography process according to Example 9; and

FIG. 17 to FIG. 21 are cross-sectional views showing a method for manufacturing a semiconductor device using a resist composition according to embodiments of the inventive concept.

### DETAILED DESCRIPTION

Embodiments of the inventive concept will be described below in more detail with reference to the accompanying drawings in order to fully understand constitutions and effects of the inventive concept. However, the inventive concept should not be limited to the embodiments set forth herein, and may be embodied in different forms and have various modifications. Rather, these embodiments are provided so that this disclosure will be thorough and complete through the descriptions in embodiments of the inventive concept, and will fully convey the scope of the inventive concept to those skilled in the art. A person skilled in the art will understand that the present inventive concept can be practiced in any suitable environment.

The terminology used herein is for the purpose of describing embodiments only and is not intended to limit the invention. As used herein, the singular forms are intended to include the plural forms as well, unless the context clearly indicates otherwise. It will be further understood that the terms “comprises” and/or “comprising”, when used in this specification, do not preclude the presence or addition of one or more other materials, components, steps, operations and/or elements.

As used herein, an alkyl group, unless otherwise specified, includes a linear, branched, or cyclic monovalent saturated hydrocarbon group.

As used herein, an alkylene group, unless otherwise specified, includes a linear, branched, or cyclic divalent saturated hydrocarbon group.

As used herein, a halogenated alkyl group is an alkyl group in which at least one hydrogen is substituted with a halogen, a halogenated alkylene is an alkylene group in which at least one hydrogen is substituted with a halogen, a halogenated aryl is an aryl group in which at least one hydrogen is substituted with a halogen, and a halogenated alkoxy group is an alkoxy group in which at least one hydrogen is substituted with a halogen.

As used herein, a fluoroalkyl is an alkyl group in which at least one hydrogen is substituted with a fluorine, a fluoroalkylene group is an alkylene group in which at least one hydrogen is substituted with a fluorine, a fluoroaryl is an aryl group in which at least one hydrogen is substituted with a fluorine, and a fluoroalkoxy group is an alkoxy group in which at least one hydrogen is substituted with a fluorine.

As used herein, “substituted” means that at least some of hydrogen atoms are substituted with a functional group or an atom other than a hydrogen atom. For example, a substituent may be at least one selected from the group consisting of a halogen, a hydroxy group, an alkoxy group, an ether group, a halogenated alkyl group, a halogenated alkoxy group, a halogenated ether group, an alkyl group, an alkenyl group, an aryl group, a hydrocarbon ring group, and a heterocycle group.

As used herein, unless otherwise defined, a case where a chemical bond is not depicted at a position where the chemical bond should be, may imply that a hydrogen atom is bonded at that position.

Hereinafter, the present invention will be explained in detail with reference to the accompanying drawings.

### Resist Composition According to Embodiments of the Inventive Concept

A resist composition according to embodiments of the inventive concept may be used in manufacture of a semiconductor device, and may be used in a photolithography process for manufacture of a semiconductor device. The resist composition may be used in, for example, an EUV or electron-beam (e-beam) lithography process. The EUV may refer to UV with a wavelength in about 10 nm to about 124 nm, specifically, a wavelength in about 13.0 nm to about 13.9 nm, or more specifically a wavelength in about 13.4 nm to about 13.6 nm.

The resist composition may include a metal oxide cluster(hereinafter, a metal-oxo cluster) represented by Formula 1.

[(R-M)₁₂O₁₄(OH)₆]²⁺[Rx⁻]₂ [Formula 1]

In Formula 1, M is a metal and is at least one selected from the group consisting of tin (Sn), zinc (Zn), lithium (Li), sodium (Na), potassium (K), beryllium (Be), magnesium (Mg), calcium (Ca), barium (Ba), aluminum (Al), silicon (Si), cadmium (Cd), mercury (Hg), chromium (Cr), iron (Fe), cobalt (Co), nickel (Ni), copper (Cu), germanium (Ge), palladium (Pd), platinum (Pt), lead (Pb), strontium (Sr), and manganese (Mn).

In Formula 1, R is an alkyl group having 1 to 20 carbons, or a halogenated alkyl group having 1 to 20 carbons, Rx⁻ is a counter anion, and is a carboxylate anion having a substituted or unsubstituted unsaturated hydrocarbon group having 2 to 20 carbons, or a sulfonate anion having a substituted or unsubstituted unsaturated hydrocarbon group having 2 to 20 carbons.
Rx⁻ may have a structure of Formula 2 or Formula 3.

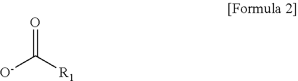

In Formula 2, R₁ is a substituted or unsubstituted unsaturated hydrocarbon group having 2 to 20 carbons, which has at least one C═C bond or at least one C≡C bond.

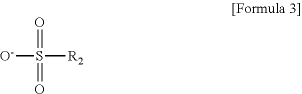

In Formula 3, R₂ is a substituted or unsubstituted unsaturated hydrocarbon group having 2 to 20 carbons, which has at least one C═C bond or at least one C≡C bond.

Rx⁻ may have a structure of, for example, CH₂=CH—CH═CHCOO⁻, CH₂=CH—CH₂—CH₂COO⁻, CH₃—CH₂—CH═CHCOO⁻, CH₂=CH—CH═CHSO₃⁻, CH₂=CH—CH₂—CH₂SO₃⁻ or CH₃—CH₂—CH═CHSO₃⁻.

The resist composition may include, for example, a tin oxide cluster(hereinafter, a tin-oxo cluster) represented by Formula 1-1.

[(R—Sn)₁₂O₁₄(OH)₆]²⁺[Rx⁻]₂ [Formula 1-1]

In Formula 1-1, R is an alkyl group having 1 to 20 carbons, or a fluoroalkyl group having 1 to 20 carbons, Rx⁻ is a counter anion and is a carboxylate anion having a substituted or unsubstituted unsaturated hydrocarbon group having 2 to 20 carbons, or a sulfonate anion having a substituted or unsubstituted unsaturated hydrocarbon group having 2 to 20 carbons. Rx⁻ may have a structure of Formula 2 or Formula 3, and have a structure of, for example, CH₂=CH—CH═CHCOO⁻, CH₂=CH—CH₂—CH₂COO⁻, CH₃—CH₂—CH═CHCOO⁻, CH₂=CH—CH═CHSO₃⁻, CH₂=CH—CH₂—CH₂SO₃⁻ or CH₃—CH₂—CH═CHSO₃⁻.

The resist composition may include, for example, a tin-oxo cluster represented by Formula 1-2.

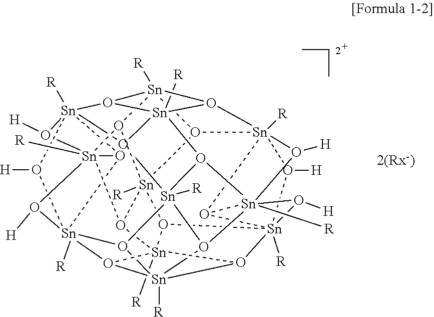

In Formula 1-2, R may be an alkyl group having 1 to 20 carbons, or a fluoroalkyl group having 1 to 20 carbons, and Rx⁻ may be CH₂=CH—CH═CHCOO⁻, CH₂=CH—CH₂—CH₂COO⁻, CH₃—CH₂—CH═CHCOO⁻, CH₂=CH—CH═CHSO₃⁻, CH₂=CH—CH₂—CH₂SO₃⁻ or CH₃—CH₂—CH═CHSO₃⁻.

The resist composition may further include an organic solvent. The organic solvent may include, for example, at least one among methyl ethyl ketone (MEK), benzotrifluoride (BTF), propylene glycol monomethyl ether (PGME), propylene glycol monomethyl ether acetate, 2-hydroxyisobutyric acid methyl ester (HBM), ethyl lactate, cyclohexanone, heptanone, or lactone.

According to the inventive concept, when an electron beam or EUV is irradiated to the resist composition, an organic ligand R may be separated from the metal-oxo cluster, and thus a metal radical (for example, tin radical) may be generated. A counter anion (Rx⁻) of the metal-oxo cluster may have an unsaturated hydrocarbon group having at least one C≡C bond or at least one C≡C bond. The at least one C═C bond or at least one C≡C bond of the counter anion (Rx⁻) may react with the metal radical (for example, tin radical) by irradiation of electron beam or EUV. That is, the metal radical (for example, tin radical) may be generated from the metal-oxo cluster due to the irradiation of electron beam or EUV, and the metal radical (for example, tin radical) of the metal-oxo cluster may react with the C═C bond or C≡C bond of the counter anion (Rx⁻). Therefore, the metal-oxo clusters adjacent to each other may be cross-linked via a chemical bond between the metal radical (for example, tin radical) and the counter anion (Rx⁻). Therefore, the crosslinking between the metal-oxo clusters within the resist composition may be accelerated, and a difference in solubility between the exposed part and the unexposed part of the resist composition may increase.

In addition, when the organic ligand R of the metal-oxo cluster represented by Formula 1 is a halogenated alkyl group (for example, fluoroalkyl group), a bond (for example, C—F bond) between carbon and a halogen atom within the organic ligand R may be broken by the irradiation of electron beam or EUV, and thus a crosslinking reaction between the organic ligands R may occur through a coupling reaction between the generated radicals (for example, carbon radicals). In this case, the metal-oxo clusters adjacent to each other may be cross-linked not only through a chemical bond between the metal radical (for example, tin radical) and the counter anion (Rx⁻) but also through a crosslinking reaction between the organic ligands R. Therefore, the crosslinking reaction between the metal-oxo clusters within the resist composition may be accelerated and the difference in solubility between the exposed part and the unexposed part may increase.

### [Example 1] Synthesis of Tin-Oxo Cluster Having Butyl Group [(Bu-Sn)₁₂O₁₄(OH)₆]²⁺[OH⁻]₂ (BTOC) (Reaction Scheme 1)

Butyl tin trichloride (3 g, 10.63 mmol) was put into a vial of 10 cm³ and an aqueous solution of 0.5 M tetramethylammonium hydroxide (TMAH) (64 cm³) was added under vigorous stirring. The mixture thus obtained was stirred for about 1 hour at a room temperature, and then filtered to obtain solids. The obtained solids were washed several times with purified water, and dried to synthesize white solids of [(Bu-Sn)₁₂O₁₄(OH)₆]²⁺[OH⁻]₂ (BTOC). (1.8 g, yield: 69%)

¹H NMR (400 MHz, acetone): δ=1.9-1.16 (m, 6H, CH₂CH₂CH₂CH₃), 1.01-0.81 (m, 2H, CH₂CH₃)

IR [(KBr): νₘₐₓ, (cm⁻¹)]3245, 2957, 2925, 1464, 1378, 671, 548

### [Example 2] Synthesis of Tin-Oxo Cluster [(Bu-Sn)₁₂O₁₄(OH)₆]²⁺[CH₂CHCHCHCOO⁻]₂(2PBTOC) of which Counter Anion is Substituted with 2,4-pentadienoate (Reaction Scheme 1)

BTOC (1 g, 0.40 mmol) prepared in Example 1 and Tetrahydrofuran (THF, 8 cm³) were added to a vial of 20 cm³ and stirred, and a solution prepared by mixing 2,4-pentadienoic acid (0.082 g, 0.80 mmol) and THF (2 cm³) was put. A reaction mixture, which is obtained above, was stirred at about 50° C. for about 10 minutes to obtain a reactant. The reactant was concentrated under reduced pressure to obtain a product in a viscous liquid form. Thereafter, the product was dissolved in THF (1 cm³), and then precipitated by dropwise addition to an excess of n-hexane. The precipitated was filtered and dried to obtain white solids of [(Bu-Sn)₁₂O₁₄(OH)₆]²⁺[CH₂CHCHCHCOO⁻]₂ (2PBTOC). (0.5 g, 63%)

¹H NMR (400 MHz, CDCl₃): δ=7.09 (t, J=12.4 Hz, 2H, 2×CHCHCOO), 6.46 (dt, J=16.8, 10.8 Hz, 2H, 2×CH₂CHCHCHCOO), 5.99 (d, J=14.8 Hz, 2H, 2×CH₂CHCHCHCOO), 5.34 (dd, J=61.2, 17.2 Hz, 4H, 2×CH₂CHCHCHCOO), 1.84-1.13 (m, 72H, 12×CH₂CH₂CH₂CH₃), 1.07-0.75 (m, 36H, 12×CH₂CH₂CH₂CH₃)

IR [(KBr): νₘₐₓ (cm⁻¹)]3245, 2975, 2925, 1643, 1601, 1539, 1392, 1280, 1183, 1127, 1076, 1036, 1009, 879

### [Example 3] Synthesis of Tin-Oxo Cluster [(Bu-Sn)₁₂O₁₄(OH)₆]²⁺[CH₂CHCH₂CH₂COO⁻]₂ (TPBTOC) of which Counter Anion is Substituted with 4-Pentenoate (Reaction Scheme 1)

BTOC (1 g, 0.40 mmol) prepared in Example 1 and Tetrahydrofuran (THF, 8 cm³) were added to a vial of 20 cm³ and stirred, and a solution prepared by mixing 4-pentenoic acid (0.084 g, 0.80 mmol) and THF (2 cm³) was put. A reaction mixture, which is obtained above, was stirred at about 50° C. for about 10 minutes to obtain a reactant. The reactant was concentrated under reduced pressure to obtain a product in a viscous liquid form. Thereafter, the product was dissolved in THF (1 cm³), and then precipitated by dropwise addition to an excess of n-hexane. The precipitated was filtered and dried to obtain white solids of [(Bu-Sn)₁₂O₁₄(OH)₆]²⁺[CH₂CHCH₂CH₂COO⁻]₂ (TPBTOC) (0.35 g, 34%).

¹H NMR (400 MHz, CDCl₃): δ=5.96-5.82 (m, 2H, 2×CHCH₂CH₂COO), 5.12-4.89 (m, 4H, 2×CH₂CHCH₂CH₂COO), 2.45-2.29 (m, 8H, 2×CH₂CH₂COO), 1.83-1.06 (m, 72H, 12×CH₂CH₂CH₂CH₃), 0.99-0.85 (m, 36H, 12×CH₂CH₃)

IR [(KBr): νₘₐₓ (cm⁻¹)]3245, 2975, 2925, 1643, 1549, 1460, 1400, 1374, 1294, 1151, 910, 872, 783, 669

### [Example 4] Synthesis of Tin-Oxo Cluster [(Bu-Sn)₁₂O₁₄(OH)₆]²⁺[CH₃CH₂CHCHCOO⁻]₂ (MPBTOC) of which Counter Anion is Substituted with 2-Pentenoate (Reaction Scheme 1)

BTOC (1 g, 0.40 mmol) prepared in Example 1 and Tetrahydrofuran (THF, 8 cm³) were added to a vial of 20 cm³ and stirred, and a solution prepared by mixing 2-pentenoic acid (0.084 g, 0.80 mmol) and THF (2 cm³) was put. A reaction mixture, which is obtained above, was stirred at about 50° C. for about 10 minutes to obtain a reactant. The reactant was concentrated under reduced pressure to obtain a product in a viscous liquid form. Thereafter, the product was dissolved in THF (1 cm³), and then precipitated by dropwise addition to an excess of n-hexane. The precipitated was filtered and dried to obtain white solids of [(Bu-Sn)₁₂O₁₄(OH)₆]²⁺[CH₃CH₂CHCHCOO⁻]₂ (MPBTOC). (0.27 g, 13%)

¹H NMR (400 MHz, CDCl₃): δ=7.06-6.89 (m, 2H, 2×CHCHCOO), 5.79 (d, J=15.6 Hz, 2H, 2×CHCOO), 2.18 (dd, J=14.4, 7.6 Hz, 4H, 2×CH₂CHCHCOO), 1.85-1.11 (m, 72H, 12×CH₂CH₂CH₂CH₃), 1.07-1.02 (m, 6H, 2×CH₃CH₂CHCHCOO), 0.97-0.83 (m, 36H, 12×CH₂CH₃)

IR [(KBr): νₘₐₓ, (cm⁻¹)]3245, 2955, 2926, 1649, 1601, 1541, 1459, 1400, 1373, 1287, 1180, 1077, 910, 870, 788, 665

### [Example 5] Synthesis of Tin-Oxo Cluster [(Bu-Sn)₁₂O₁₄(OH)₆]²⁺[CH₃CH₂CH₂CH₂COO⁻]₂ (PBTOC) of which Counter Anion is Substituted with Pentanoate (Reaction Scheme 1)

BTOC (1 g, 0.40 mmol) prepared in Example 1 and Tetrahydrofuran (THF, 8 cm³) were added to a vial of 20 cm³ and stirred, and a solution prepared by mixing pentanoic acid (0.083 g, 0.80 mmol) and THF (2 cm³) was put. A reaction mixture, which is obtained above, was stirred at about 50° C. for about 10 minutes to obtain a reactant. The reactant was concentrated under reduced pressure to obtain a product in a viscous liquid form. Thereafter, the product was dissolved in THF (1 cm³), and then precipitated by dropwise addition to an excess of n-hexane. The precipitated was filtered and dried to obtain white solids of [(Bu-Sn)₁₂O₁₄(OH)₆]²⁺[CH₃CH₂CH₂CH₂COO⁻]₂ (PBTOC). (0.4 g, 37%)

¹H NMR (400 MHz, CDCl₃): δ=2.24-2.15 (br, 4H, 2×CH₂COO), 1.82-1.06 (m, 80H, 12×CH₂CH₂CH₂CH₃+2×CH₂CH₂CH₂COO), 0.99-0.84 (m, 42H, 12×CH₂CH₃+2×CH₃CH₂CH₂CH₂COO)

IR [(KBr): νₘₐₓ, (cm⁻¹)]3245, 2955, 2926, 1546, 1457, 1399, 1374, 1343, 1291, 1077, 964, 870, 671

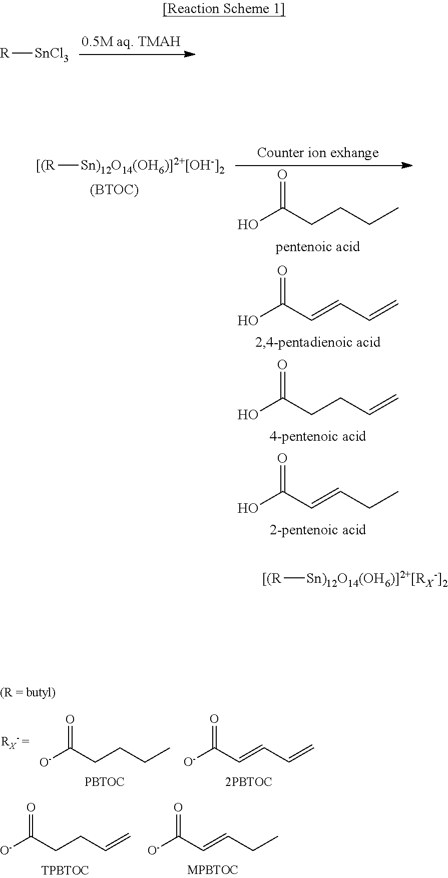

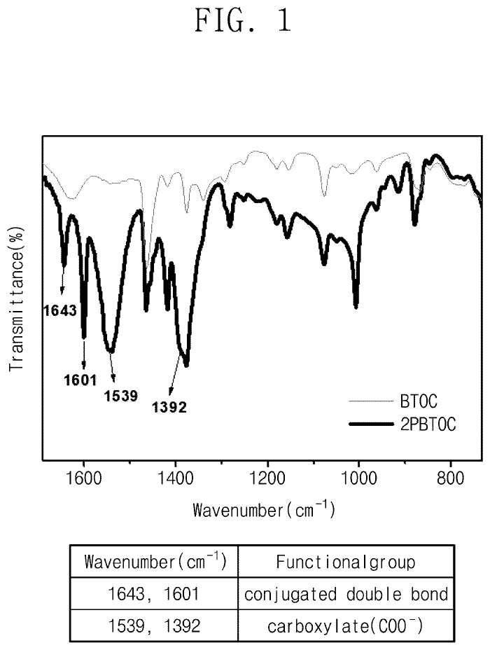

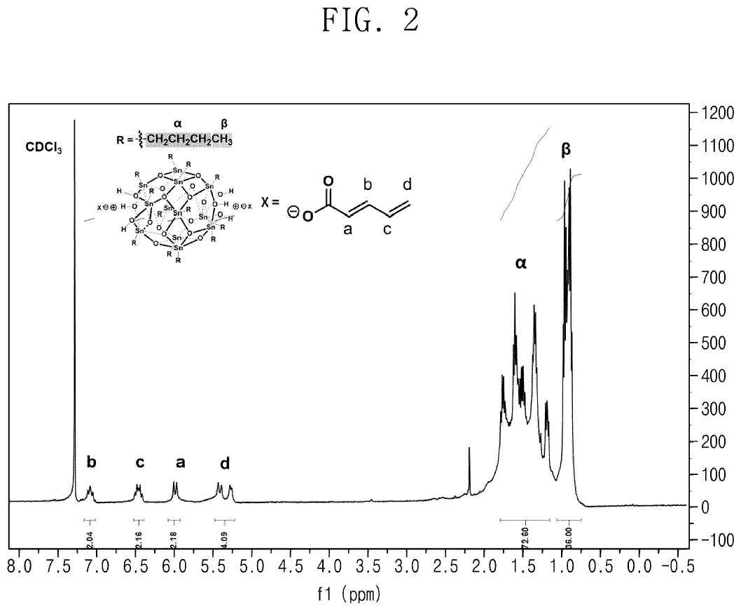

FIG. 1 is a view illustrating Fourier transform infrared (FTIR) spectra of BTOC synthesized according to Example 1 and 2PBTOC synthesized according to Example 2. FIG. 2 is a view illustrating a ¹H NMR spectrum of 2PBTOC synthesized according to Example 2.

Referring to FIG. 1 and FIG. 2, it can be confirmed that a counter anion (OH⁻) of BTOC synthesized according to Example 1 is substituted with 2,4-pentadienoic acid, thereby producing 2PBTOC according to Example 2.

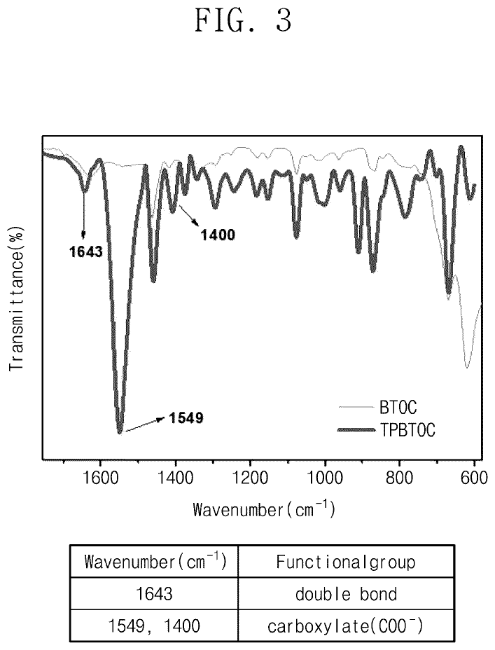

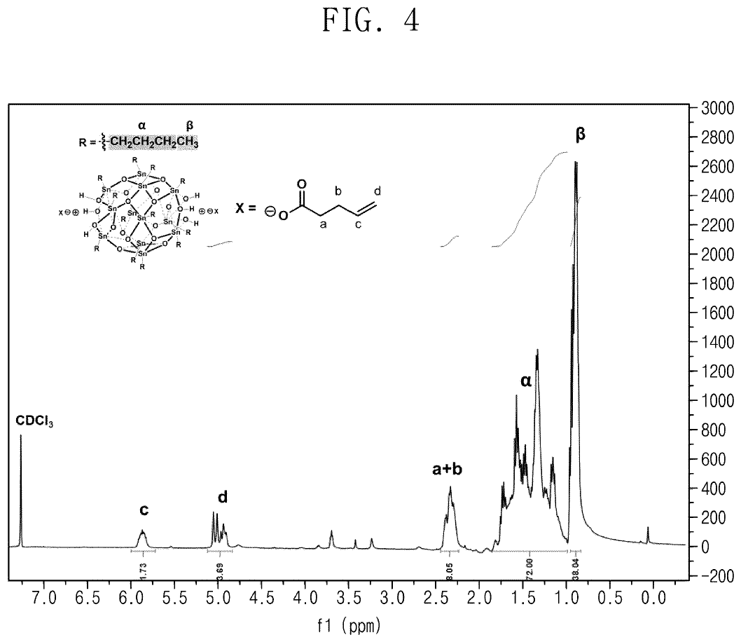

FIG. 3 is a view illustrating Fourier Transform Infrared (FTIR) spectra of BTOC synthesized according to Example 1 and TPBTOC synthesized according to Example 3. FIG. 4 is a view illustrating a ¹H NMR spectrum of TPBTOC synthesized according to Example 3.

Referring to FIG. 3 and FIG. 4, it can be confirmed that a counter anion (OH⁻) of BTOC synthesized according to Example 1 is substituted with 4-pentenoic acid, thereby producing TPBTOC according to Example 3.

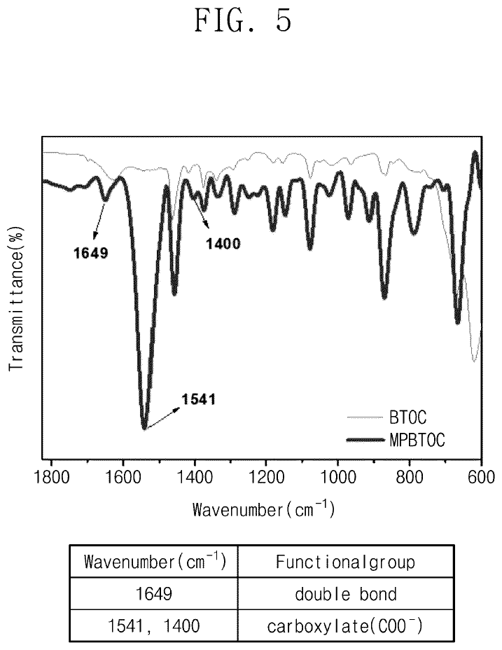

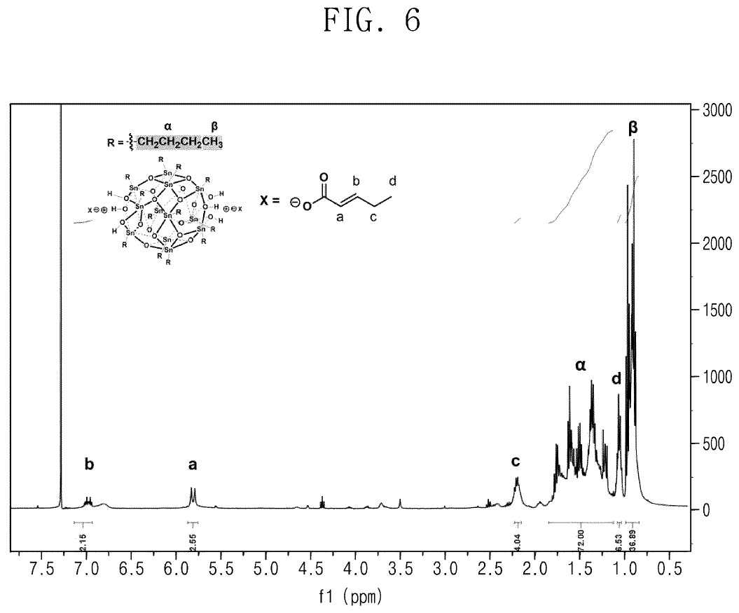

FIG. 5 is a view illustrating Fourier Transform Infrared (FTIR) spectra of BTOC synthesized according to Example 1 and MPBTOC synthesized according to Example 4. FIG. 6 is a view illustrating a ¹H NMR spectrum of MPBTOC synthesized according to Example 4.

Referring to FIG. 5 and FIG. 6, it can be confirmed that a counter anion (OH⁻) of BTOC synthesized according to Example 1 is substituted with 2-pentenoic acid, thereby producing MPBTOC according to Example 4.

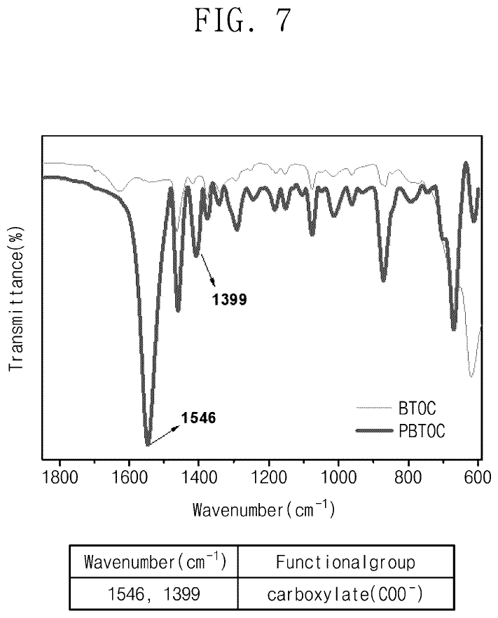

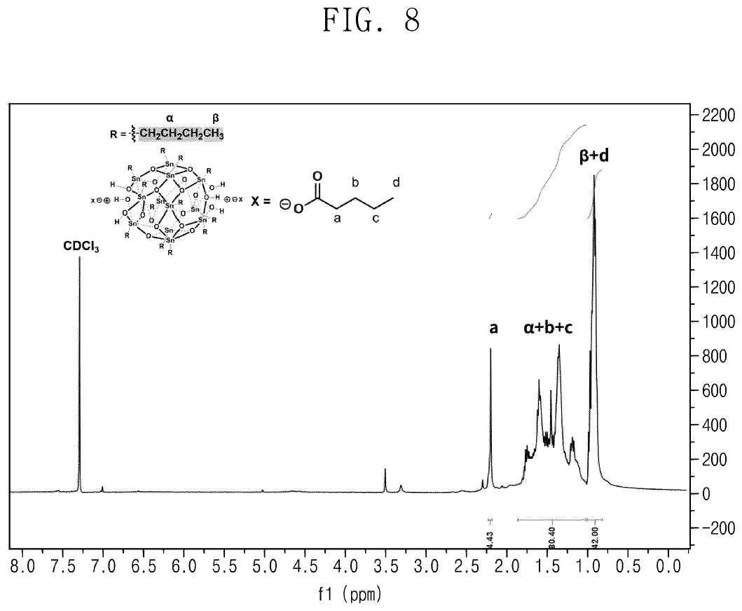

FIG. 7 is a view illustrating Fourier Transform Infrared (FTIR) spectra of BTOC synthesized according to Example 1 and PBTOC synthesized according to Example 5. FIG. 8 is a view illustrating a ¹H NMR spectrum of PBTOC synthesized according to Example 5.

Referring to FIG. 7 and FIG. 8, it can be confirmed that a counter anion (OH⁻) of BTOC synthesized according to Example 1 is substituted with pentanoic acid, thereby producing PBTOC according to Example 5.

### [Example 6] Synthesis of Tin-Oxo Cluster [(CF₃(CF₂)₅CH₂CH₂—Sn)₁₂O₁₄(OH)₆]²⁺[CH₂CHCHCHCOO⁻]₂ (2PTOC6) of which Counter Anion is Substituted with 2,4-Pentadienoate (Reaction Scheme 2)

A mixed solvent of benzotrifluoride (BTF, 3.0 cm³) and Tetrahydrofuran (THF, 3.0 cm³), and TOC6 (0.7 g, 0.11 mmol, synthesized as described in Korean patent application No. 10-2022-0072386) were added to a vial of 20 cm³ and stirred, and a solution prepared by mixing 2,4-pentadienoic acid (0.023 g, 0.23 mmol) and THF (1.0 cm³) was put. A reaction mixture, which is obtained above, was stirred at about 50° C. for about 40 minutes to obtain a reactant. The reactant was concentrated under reduced pressure to obtain a product in a viscous liquid form. Thereafter, the product was dissolved in BTF (3.0 cm³), and then precipitated by dropwise addition to an excess of toluene. The precipitated was filtered and dried to obtain white solids of [(CF₃(CF₂)₅CH₂CH₂Sn)₁₂O₁₄(OH)₆]²⁺(CH₂CHCHCHCOO⁻)₂ (2PTOC6). (0.4 g, 56%)

¹H NMR (400 MHz, acetone-d6): δ=7.23-7.02 (br, 2H, 2×CHCHCOO), 6.56-6.27 (br, 2H, 2×CHCHCHCOO), 5.99-5.71 (br, 2H, 2×CHCOO), 5.58-5.13 (br, 4H, 2×CH₂CHCHCHCOO), 2.78-2.43 (br, 24H, 12×CH₂CH₂CF₂), 1.89-0.63 (br, 24H, 12×CH₂CH₂CF₂);

¹⁹F NMR (376 MHz, acetone-d6): δ=−81.97, −116.98, −122.66, −122.63, −127.02

IR [(KBr): νₘₐₓ (cm⁻¹)]1645, 1604, 1535, 1397, 1238, 1207, 1145, 733, 702, 698, 559, 521

### [Example 7] Synthesis of Tin-Oxo Cluster [(CF₃(CF₂)₅CH₂CH₂—Sn)₁₂O₁₄(OH)₆]²⁺[CH₃CH₂CH₂CH₂COO⁻]₂ (PTOC6) of which Counter Anion is Substituted with Pentanoate (Reaction Scheme 2)

A mixed solvent of benzotrifluoride (BTF, 3.0 cm³) and Tetrahydrofuran (THF, 3.0 cm³) and TOC6 (0.7 g, 0.11 mmol, synthesized as described in Korean patent application No. 10-2022-0072386) were added to a vial of 20 cm³ and stirred, and a solution prepared by mixing pentanoic acid (0.024 g, 0.23 mmol) and THF (1.0 cm³) was put. A reaction mixture, which is obtained above, was stirred at about 50° C. for about 40 minutes to obtain a reactant. The reactant was concentrated under reduced pressure to obtain a product in a viscous liquid form. Thereafter, the product was dissolved in BTF (3.0 cm³), and then precipitated by dropwise addition to an excess of toluene. The precipitated was filtered and dried to obtain white solids of [(CF₃(CF₂)₅CH₂CH₂Sn)₁₂O₁₄(OH)₆]²⁺(CH₃CH₂CH₂CH₂COO⁻)₂ (PTOC6). (0.45 g, 63%)

¹H NMR (400 MHz, acetone-d6): δ=2.79-2.36 (br, 28H, 12×CH₂CH₂CF₂+2×CH₂COO), 1.82-0.61 (br, 32H, 12×CH₂CH₂CF₂+2×CH₂CH₂CH₂COO), 0.89 (t, J=7.2 Hz, 6H, 2×CH₃CH₂CH₂CH₂COO);

¹⁹F NMR (376 MHz, acetone-d6): δ=−82.00, −117.05, −122.69, −123.59, −127.00

IR [(KBr): νₘₐₓ, (cm⁻¹)]1544, 1404, 1238, 1207, 1145, 733, 702, 698, 559, 521

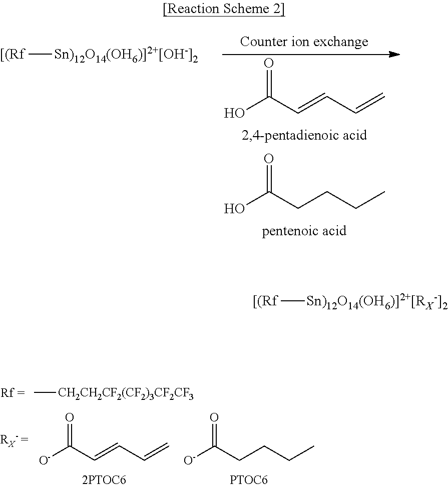

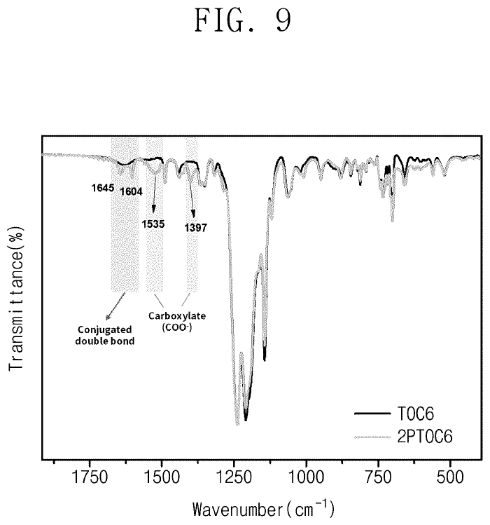

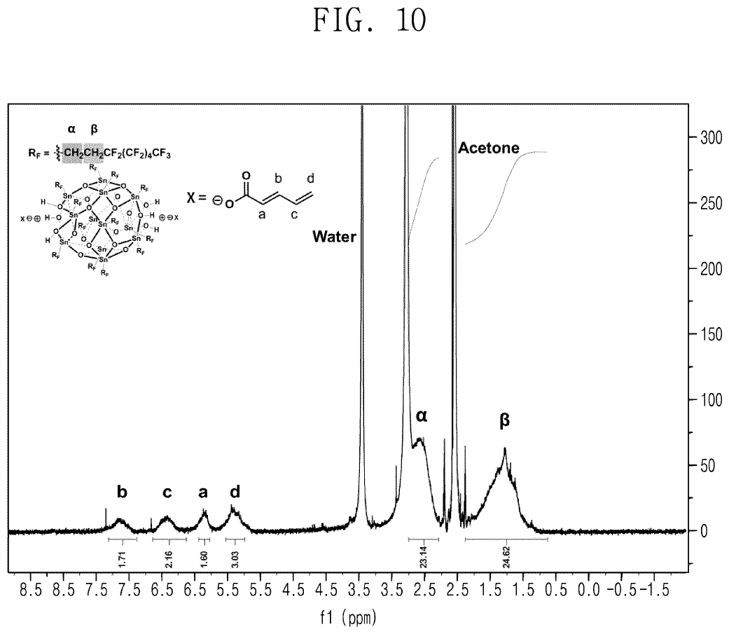

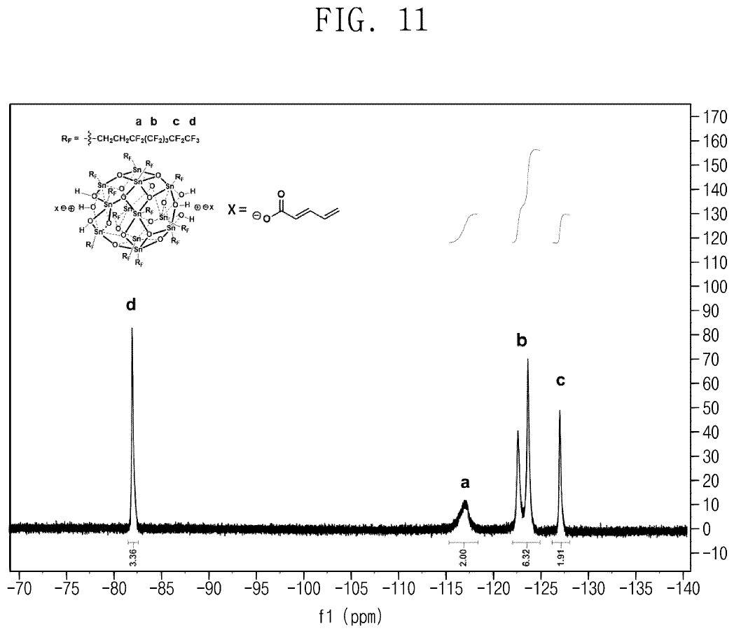

FIG. 9 is a view illustrating a Fourier transform infrared (FTIR) spectrum of 2PTOC6 formed through an anionic substitution reaction of TOC6 according to Example 6. FIG. 10 is a view illustrating a ¹H NMR spectrum of 2PTOC6 synthesized according to Example 6, and FIG. 11 is a view illustrating a ¹⁹F NMR spectrum of 2PTOC6 synthesized according to Example 6.

Referring to FIG. 9 to FIG. 11, it can be confirmed that a counter anion (OH⁻) of TOC6 is substituted with 2,4-pentadienoic acid, thereby producing 2PTOC6 according to Example 6.

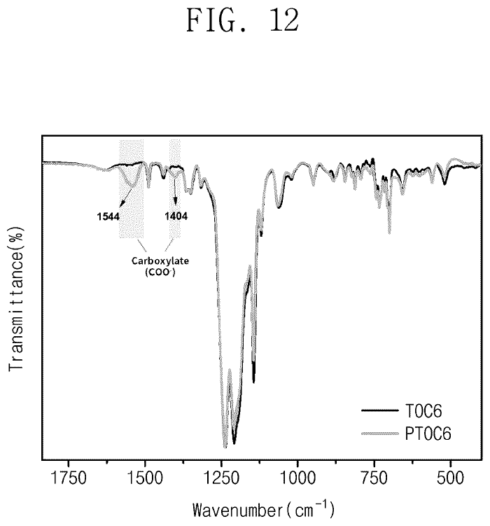

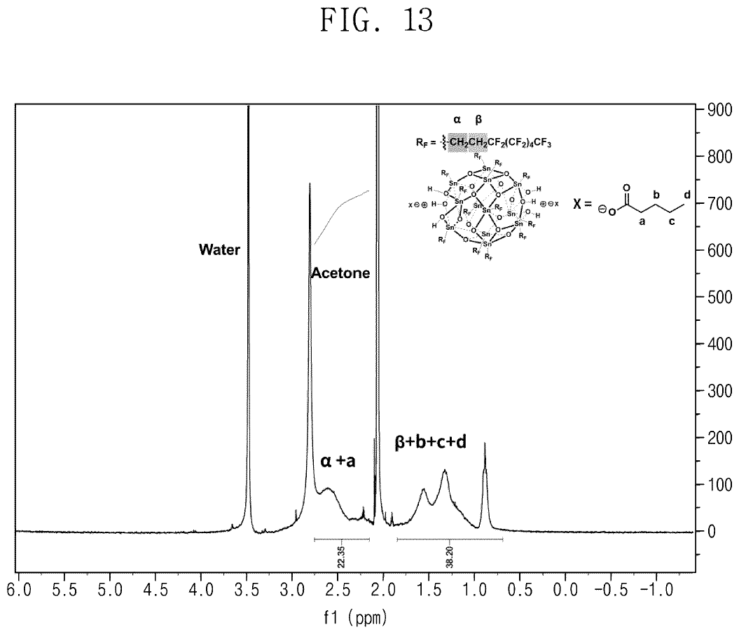

FIG. 12 is a view illustrating a Fourier transform infrared (FTIR) spectrum of PTOC6 formed through an anionic substitution reaction of TOC6 according to Example 7. FIG. 13 is a view illustrating a ¹H NMR spectrum of PTOC6 synthesized according to Example 7, and FIG. 14 is a view illustrating a ¹⁹F NMR spectrum of PTOC6 synthesized according to Example 7.

Referring to FIG. 12 to FIG. 14, it can be confirmed that a counter anion (OH⁻) of TOC6 is substituted with pentanoic acid, thereby producing PTOC6 according to Example 7.

### [Example 8] Electron Beam Lithography Evaluation-Evaluation of Changes in Solubility of Resist Thin Film

### 1) 2PBTOC

2PBTOC synthesized according to Example 2 was dissolved in methyl ethyl ketone (MEK) to prepare a solution of 3 wt/vol %. The solution was spin-coated onto a silicon substrate pretreated with 1,3-divinyl-1,1,3,3-tetramethyldisilazane (DVS) at about 2000 rpm for about 60 seconds. The coated substrate was heated at about 80° C. for about 1 minute to form a resist thin film (thickness of about 100 nm). An electron beam of about 50 μC/cm² to about 1500 μC/cm² was irradiated to the resist thin film under an accelerating voltage of about 80 keV and a post-exposure bake (PEB) process was carried out at about 150° C. for about 2 minutes. Thereafter, the substrate irradiated with the electron beam was subject to a developing process using 2-heptanone for about 30 seconds to form a negative tone resist pattern. Thereafter, a thickness of the resist pattern (that is, the thickness of the resist pattern remained after the developing process) was measured using Alpha-step® D-300 stylus profiler made by Kla-Tencor Corporation to evaluate a change in solubility of the resist thin film.

### 2) TPBTOC

TPBTOC synthesized according to Example 3 was dissolved in methyl ethyl ketone (MEK) to prepare a solution of 3 wt/vol %. The solution was spin-coated onto a silicon substrate pretreated with 1,3-divinyl-1,1,3,3-tetramethyldisilazane (DVS) at about 2000 rpm for about 60 seconds. The coated substrate was heated at about 80° C. for about 1 minute to form a resist thin film (thickness of about 100 nm). An electron beam of about 50 μC/cm² to about 1500 μC/cm² was irradiated to the resist thin film under an accelerating voltage of about 80 keV and a post-exposure bake (PEB) process was carried out at about 150° C. for about 2 minutes. Therefore, the substrate irradiated with the electron beam was subject to a developing process using 2-heptanone for about 30 seconds to form a negative tone resist pattern. Thereafter, a thickness of the resist pattern (that is, the thickness of the resist pattern remained after the developing process) was measured using Alpha-step® D-300 stylus profiler made by Kla-Tencor Corporation to evaluate a change in solubility of the resist thin film.

### 3) MPBTOC

MPBTOC synthesized according to Example 4 was dissolved in methyl ethyl ketone (MEK) to prepare a solution of 3 wt/vol %. The solution was spin-coated onto a silicon substrate pretreated with 1,3-divinyl-1,1,3,3-tetramethyldisilazane (DVS) at about 2000 rpm for about 60 seconds. The coated substrate was heated at about 80° C. for about 1 minute to form a resist thin film (thickness of about 100 nm). An electron beam of about 50 μC/cm² to about 1500 μC/cm² was irradiated to the resist thin film under an accelerating voltage of about 80 keV and a post-exposure bake (PEB) process was carried out at about 150° C. for about 2 minutes. Thereafter, the substrate irradiated with the electron beam was subject to a developing process using 2-heptanone for about 30 seconds to form a negative tone resist pattern. Thereafter, a thickness of the resist pattern (that is, the thickness of the resist pattern remained after the developing process) was measured using Alpha-step® D-300 stylus profiler made by Kla-Tencor Corporation to evaluate a change in solubility of the resist thin film.

### 4) PBTOC

PBTOC synthesized according to Example 5 was dissolved in methyl ethyl ketone (MEK) to prepare a solution of 3 wt/vol %. The solution was spin-coated onto a silicon substrate pretreated with 1,3-divinyl-1,1,3,3-tetramethyldisilazane (DVS) at about 2000 rpm for about 60 seconds. The coated substrate was heated at about 80° C. for about 1 minute to form a resist thin film (thickness of about 100 nm). An electron beam of about 50 μC/cm² to about 1500 μC/cm² was irradiated to the resist thin film under an accelerating voltage of about 80 keV and a post-exposure bake (PEB) process was carried out at about 150° C. for about 2 minutes. Thereafter, the substrate irradiated with the electron beam was subject to a developing process using 2-heptanone for about 30 seconds to form a negative tone resist pattern. Thereafter, a thickness of the resist pattern (that is, the thickness of the resist pattern remained after the developing process) was measured using Alpha-step® D-300 stylus profiler made by Kla-Tencor Corporation to evaluate a change in solubility of the resist thin film.

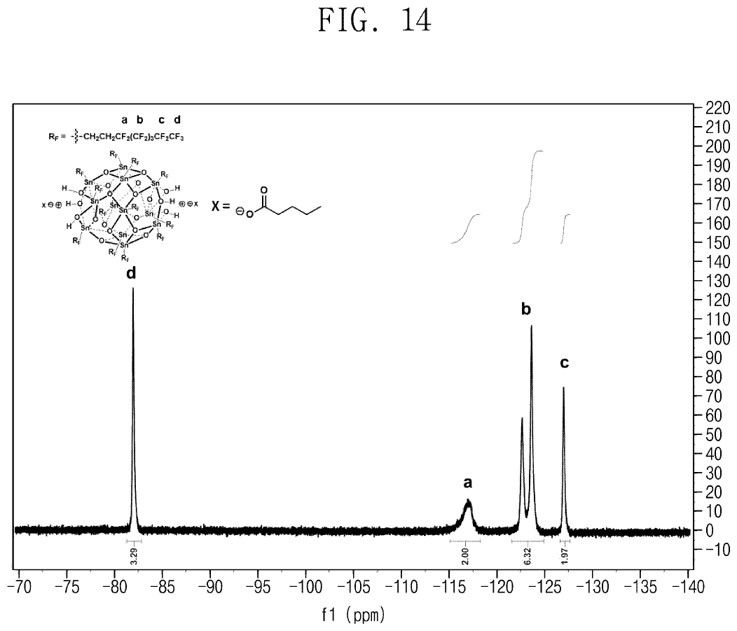

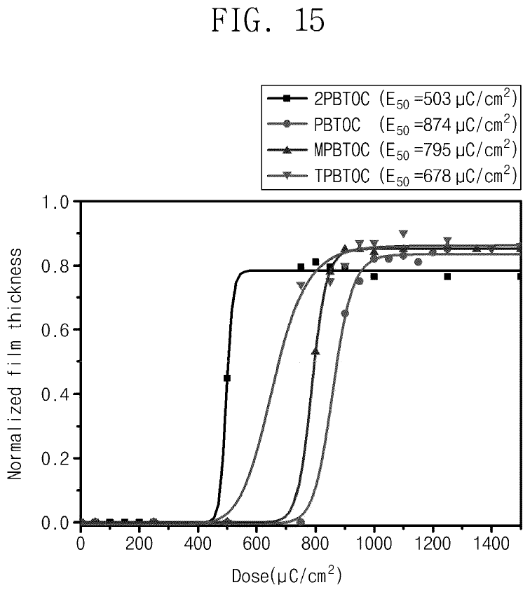

FIG. 15 is a view showing evaluation results of changes in solubility of a resist film for an electron beam lithography process according to Example 8.

Referring to FIG. 15, in a case of 2PBTOC resist thin film, it can be seen that, when electron beam of about 503 μC/cm² is irradiated onto the resist thin film, a thickness of the resist pattern may be maintained as about 50% of the thickness of the resist thin film. In a case of TPBTOC resist thin film, it can be seen that, when electron beam of about 678 μC/cm² is irradiated onto the resist thin film, a thickness of the resist pattern may be maintained as about 50% of the thickness of the resist thin film. In a case of MPBTOC resist thin film, it can be seen that, when electron beam of about 795 μC/cm² is irradiated onto the resist thin film, a thickness of the resist pattern may be maintained as about 50% of the thickness of the resist thin film. In a case of PBTOC resist thin film, it can be seen that, when electron beam of about 874 μC/cm² is irradiated onto the resist thin film, a thickness of the resist pattern may be maintained as about 50% of the thickness of the resist thin film.

In cases of 2PBTOC, TPBTOC, and MPBTOC resist films in which the counter anion of the tin-oxo cluster has an unsaturated hydrocarbon group, it can be confirmed that, a resist pattern may be formed using small amounts of electron beam irradiation, compared to that of the PBTOC resist thin film in which the counter anion of the tin-oxo cluster has a saturated hydrocarbon group. That is, since the unsaturated hydrocarbon group is introduced to the counter anion of tin-oxo cluster, sensitivity of resist thin film for the electron beam lithography may increase.

In addition, in a case of 2PBTOC resist thin film, it can be confirmed that a resist pattern may be formed using small amounts of electron beam irradiation, compared to those of the TPBTOC and MPBTOC resist thin films. That is, the sensitivity of the resist thin film to the electron beam lithography may increase as the number of multiple bonds between carbons (for example, carbon-carbon double bond) in the unsaturated hydrocarbon group in the counter anion of the tin-oxo cluster, increases. In addition, in a case of TPBTOC resist thin film, it can be confirmed that a resist pattern may be formed using small amounts of electron beam irradiation, compared to that of the MPBTOC resist thin film. That is, the sensitivity of the resist film to electron beam lithography may increase as multiple bonds between carbons (for example, carbon-carbon double bond) is present at the end of the unsaturated hydrocarbon group in the counter anion of the tin-oxo cluster.

### [Example 9] Electron Beam Lithography Evaluation-Forming Resist Pattern

### 1) 2PBTOC

2PBTOC synthesized according to Example 2 was dissolved in methyl ethyl ketone (MEK) to prepare a solution of 3 wt/vol %. The solution was spin-coated onto a silicon substrate pretreated with 1,3-divinyl-1,1,3,3-tetramethyldisilazane (DVS) at about 2000 rpm for about 60 seconds. The coated substrate was heated at about 80° C. for about 1 minute to form a resist thin film (thickness of about 100 nm). An electron beam of about 50 μC/cm² to about 1500 μC/cm² was irradiated to the resist thin film under an accelerating voltage of about 80 keV and a post-exposure bake (PEB) process was carried out at about 150° C. for about 2 minutes. Thereafter, the substrate irradiated with the electron beam was subject to a developing process using 2-heptanone for about 3 minutes to form a negative tone resist pattern in a size of about 70 nm to about 100 nm.

### 2) TPBTOC

TPBTOC synthesized according to Example 3 was dissolved in methyl ethyl ketone (MEK) to prepare a solution of 3 wt/vol %. The solution was spin-coated onto a silicon substrate pretreated with 1,3-divinyl-1,1,3,3-tetramethyldisilazane (DVS) at about 2000 rpm for about 60 seconds. The coated substrate was heated at about 80° C. for about 1 minute to form a resist thin film (thickness of about 100 nm). An electron beam of about 50 μC/cm² to about 1500 μC/cm² was irradiated to the resist thin film under an accelerating voltage of about 80 keV and a post-exposure bake (PEB) process was carried out at about 150° C. for about 2 minutes. Thereafter, the substrate irradiated with the electron beam was subject to a developing process using 2-heptanone for about 30 seconds to form a negative tone resist pattern in a size of about 70 nm to about 100 nm.

### 3) MPBTOC

MPBTOC synthesized according to Example 4 was dissolved in methyl ethyl ketone (MEK) to prepare a solution of 3 wt/vol %. The solution was spin-coated onto a silicon substrate pretreated with 1,3-divinyl-1,1,3,3-tetramethyldisilazane (DVS) at about 2000 rpm for about 60 seconds. The coated substrate was heated at about 80° C. for about 1 minute to form a resist thin film (thickness of about 100 nm). An electron beam of about 50 μC/cm² to about 1500 μC/cm² was irradiated to the resist thin film under an accelerating voltage of about 80 keV and a post-exposure bake (PEB) process was carried out at about 150° C. for about 2 minutes. Thereafter, the irradiated substrate with the electron beam was subject to a developing process using 2-heptanone for about 30 seconds to form a negative tone resist pattern in a size of about 70 nm to about 100 nm.

### 4) PBTOC

PBTOC synthesized according to Example 5 was dissolved in methyl ethyl ketone (MEK) to prepare a solution of 3 wt/vol %. The solution was spin-coated onto a silicon substrate pretreated with 1,3-divinyl-1,1,3,3-tetramethyldisilazane (DVS) at about 2000 rpm for about 60 seconds. The coated substrate was heated at about 80° C. for about 1 minute to form a resist thin film (thickness of about 100 nm). An electron beam of about 50 μC/cm² to about 1500 μC/cm² was irradiated to the resist thin film under an accelerating voltage of about 80 keV and a post-exposure bake (PEB) process was carried out at about 150° C. for about 2 minutes. Thereafter, the substrate irradiated with the electron beam was subject to a developing process using 2-heptanone for about 5 seconds to form a negative tone resist pattern in a size of about 70 nm to about 100 nm.

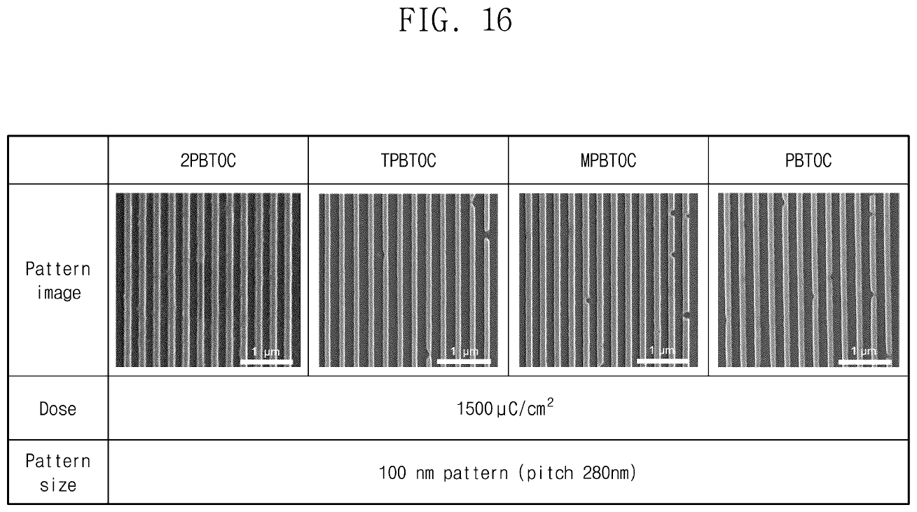

FIG. 16 is scanning electron microscope images of a negative tone resist pattern formed by a lithography process according to Example 9.

Referring to FIG. 16, it can be confirmed that as a result of performing the electron beam lithography on the resist thin films of 2PBTOC, TPBTOC and MPBTOC, in which the counter anion of tin-oxo cluster has an unsaturated hydrocarbon group, resist patterns having a linewidth of about 100 nm and a pitch of about 280 nm are formed. In addition, in a case where the electron beam lithography is performed on the resist thin film of PBTOC in which the counter anion of tin-oxo cluster has a saturated hydrocarbon group, it can be also confirmed that resist pattern having a linewidth of about 100 nm and a pitch of about 280 nm are formed.

### Method for Manufacturing Semiconductor Device Using Resist Composition According to Embodiments of the Inventive Concept

FIG. 17 to FIG. 21 are cross-sectional views showing a method for manufacturing a semiconductor device using a resist composition according to embodiments of the inventive concept.

Referring to FIG. 17, an etching target layer 110 may be formed on a substrate 100, a photoresist film 120 may be formed on the etching target layer 110. The substrate 100 may be a semiconductor substrate, and may be, for example, a silicon substrate, a germanium substrate, or a silicon/germanium substrate. The etching target layer 110 may be formed using any one selected from a semiconductor material, a conductive material, and an insulation material, or a combination thereof. The etching target layer 110 may be formed using a single layer or may include a plurality of layers stacked on the substrate 100.

The photoresist film 120 may contain the resist composition according to embodiments of the inventive concept. The resist composition may include a metal-oxo cluster represented by Formula 1. The formation of the photoresist film 120 may include, for example, applying the resist composition onto the etching target layer 110 using a spin coating method. The formation of the photoresist film 120 may further include performing a heat-treatment process (for example, soft baking process) on the resist composition applied.

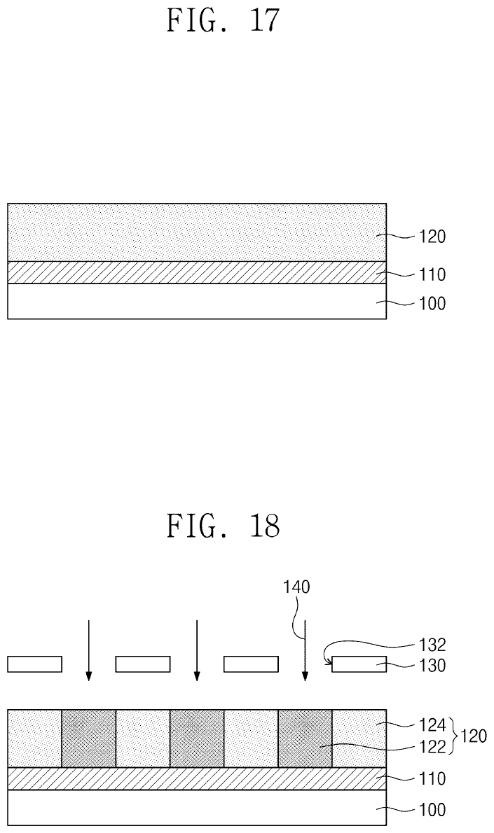

Referring to FIG. 18, an exposure process may be performed on the photoresist film 120. The exposure process may include irradiating light 140 on the photoresist film 120. The light 140 may be EUV or electron beam. For example, the exposure process may include aligning a photomask 130 on top of the photoresist film 120 and irradiating the light 140 (for example, EUV) onto the photoresist film 120 through the photomask 130. For another example, the exposure process may include irradiation the light 140 (for example, electron beam) onto the photoresist film 120 and scanning, using an electron beam lithography apparatus.

The photoresist film 120 may include a first portion 122 which is exposed to the light 140, and a second portion 124 which is unexposed to the light 140. For example, the light 140 may be irradiated to the first portion 122 through an opening part 132 of the photomask 130, and may be unirradiated to the second portion 124 due to blocking of the photomask 130.

When the light 140 is irradiated to the resist composition, an organic ligand R may be separated from the metal-oxo cluster represented by Formula 1, and thus a metal radical (for example, tin radical) may be generated. The counter anion (Rx⁻) of the metal-oxo cluster may have an unsaturated hydrocarbon group having at least one C═C bond, or at least one C≡C bond. By the irradiation of the light 140, the metal radical (for example, tin radical) of the metal-oxo cluster may react with the at least one C═C bond, or at least one C≡C bond of the counter anion (Rx⁻). Therefore, the metal-oxo clusters adjacent to each other may be cross-linked via a chemical bond between the metal radical (for example, tin radical) and the counter anion (Rx⁻).

The first portion 122 of the photoresist film 120 may include a macromolecular structure that is formed by crosslinking of the metal-oxo clusters represented by Formula 1. The second portion 124 of the photoresist film 120 may include the metal-oxo cluster represented by Formula 1. The first portion 122 and the second portion 124 of the photoresist film 120 may have different chemical structure due to the exposure process.

According to the inventive concept, since the counter anion (Rx⁻) of the metal-oxo cluster has an unsaturated hydrocarbon group having at least one C═C bond, or at least one C≡C bond, the metal-oxo clusters in the first portion 122 of the photoresist film 120 may be cross-linked via a chemical bond between the metal radical (for example, tin radical) and the counter anion (Rx⁻), and thus the crosslinking between the metal-oxo clusters may be accelerated in the first portion 122 of the photoresist film 120. Therefore, a difference in solubility between the first portion 122 and the second portion 124 may increase.

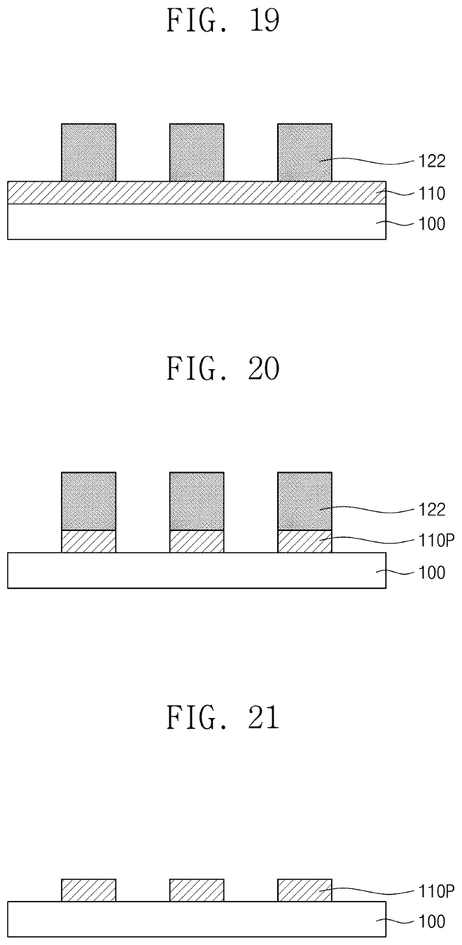

Referring to FIG. 19, the photomask 130 may be removed after the exposure process. According to some embodiments, a heat-treatment process (for example, post exposure bake) may be performed on the exposed photoresist film 120.

A developing process may be performed on the exposed photoresist film 120. Performing the developing process may include removing the second portion 124 of the photoresist film 120. The developing solution may include an organic solvent such as 2-heptanone. The second portion 124 of the photoresist film 120 may be selectively removed by the developing process. The first portion 122 of the photoresist film 120 may be referred to as a photoresist pattern, and the photoresist pattern 122 may be a pattern of negative tone.

Referring to FIG. 20, the etching target layer 110 may be etched using the photoresist pattern 122 as an etching mask. The etching of etching target layer 110 may include, for example, performing a wet or dry etching process. A lower pattern 110P may be formed by etching the etching target layer 110. The lower pattern 110P may be a semiconductor pattern, a conductive pattern, or an insulation pattern within a semiconductor device.

Referring to FIG. 21, after forming the lower pattern 110P, the photoresist pattern 122 may be removed. The photoresist pattern 122 may be removed by, for example, an ashing and/or strip process.

According to embodiments of the inventive concept, the resist composition may include a metal-oxo cluster represented by Formula 1, and a counter anion (Rx⁻) of the metal-oxo cluster may include an unsaturated hydrocarbon group having at least one C═C bond, or at least one C≡C bond. When EUV or electron-beam is irradiated on the photoresist film 120 formed using the resist composition, the unsaturated hydrocarbon group of the counter anion (Rx⁻) of the metal-oxo cluster may involve a crosslinking between metal-oxo clusters in the exposed part of the photoresist film 120, and thus the crosslinking between the metal-oxo clusters may be accelerated in the exposed part of the photoresist film 120. Therefore, a solubility difference between the exposed part and unexposed part of the photoresist film 120 may increase, and as a result, the photoresist film 120 may have excellent sensitivity and resolution for the electron beam or EUV lithography process. In addition, since the resist composition includes in the metal-oxo cluster represented by Formula 1, etch resistance of the photoresist film 120 may increase.

According to the inventive concept, the resist composition may include a metal-oxo cluster represented by Formula 1, and a counter anion (Rx⁻) may have an unsaturated hydrocarbon group having at least one C═C bond or at least one C≡C bond. When EUV or electron beam is irradiated onto the photoresist film formed using the resist composition, the unsaturated hydrocarbon group of the counter anion (Rx⁻) of the metal-oxo cluster may involve in a crosslinking between the metal-oxo clusters in an exposed part of the photoresist film, and thus the crosslinking between the metal-oxo clusters may be accelerated in the exposed part of the photoresist film. Therefore, a difference in solubility between the exposed part and the unexposed part of the photoresist film may increase. That is, since the unsaturated hydrocarbon group is introduced to the counter anion (Rx⁻) of the metal-oxo cluster, the sensitivity of the photoresist film may increase for the EUV or electron beam lithography process.

Therefore, the photoresist pattern formed using the photoresist film may have excellent sensitivity and resolution for the electron beam or EUV lithography process. In addition, since the resist composition includes the metal-oxo cluster represented by Formula 1, the photoresist pattern may have improved etch resistance.

Hitherto, although the embodiments of the present invention have been described with reference to preferable embodiments, it is understood that the present invention should not be limited to these embodiments, but various changes and modifications can be made by one ordinary skilled in the art within the spirit and scope of the present invention as hereinafter claimed.

What is claimed is:

1. A resist composition for photolithography comprising a metal-oxo cluster represented by Formula 1:
[(R-M)₁₂O₁₄(OH)₆]²⁺[Rx⁻]₂ [Formula 1]
wherein, in Formula 1 above,
M is a metal and is at least one selected from the group consisting of tin (Sn), zinc (Zn), lithium (Li), sodium (Na), potassium (K), beryllium (Be), magnesium (Mg), calcium (Ca), barium (Ba), aluminum (Al), silicon (Si), cadmium (Cd), mercury (Hg), chromium (Cr), iron (Fe), cobalt (Co), nickel (Ni), copper (Cu), germanium (Ge), palladium (Pd), platinum (Pt), lead (Pb), strontium (Sr), and manganese (Mn),
R is an alkyl group having 1 to 20 carbons, or a halogenated alkyl group having 1 to 20 carbons, and
Rx⁻ is a counter anion and is a carboxylate anion having a substituted or unsubstituted unsaturated hydrocarbon group having 2 to 20 carbons, or a sulfonate anion having a substituted or unsubstituted unsaturated hydrocarbon group having 2 to 20 carbons.

2. The resist composition of claim 1, wherein, Rx⁻ in Formula 1 above has a structure of Formula 2 or Formula 3: 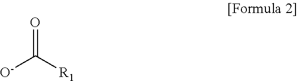
where, in Formula 2, R₁ is a substituted or unsubstituted unsaturated hydrocarbon group having 2 to 20 carbons that comprises at least one C═C bond, or at least one C≡C bond: 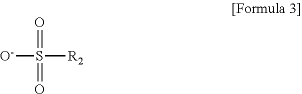
where, in Formula 3, R₂ is a substituted or unsubstituted unsaturated hydrocarbon group having 2 to 20 carbons that comprises at least one C═C bond, or at least one C≡C bond.

3. The resist composition of claim 1, wherein, Rx⁻ in Formula 1 above has a structure of CH₂=CH—CH═CHCOO⁻, CH₂=CH—CH₂—CH₂COO⁻, CH₃—CH₂—CH═CHCOO⁻, CH₂=CH—CH═CHSO₃⁻, CH₂=CH—CH₂—CH₂SO₃⁻ or CH₃—CH₂—CH═CHSO₃⁻.

4. The resist composition of claim 1,
wherein, in Formula 1 above, M is tin (Sn), and
R is an alkyl group having 1 to 20 carbons, or a fluoroalkyl group having 1 to 20 carbons.

5. The resist composition of claim 4, wherein, Rx⁻ in Formula 1 above has a structure of Formula 2 or Formula 3: 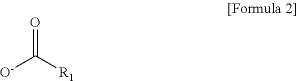
where, in Formula 2, R₁ is a substituted or unsubstituted unsaturated hydrocarbon group having 2 to 20 carbons that comprises at least one C═C bond, or at least one C≡C bond: 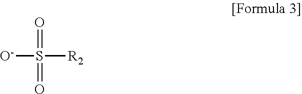
where, in Formula 3, R₂ is a substituted or unsubstituted unsaturated hydrocarbon group having 2 to 20 carbons that comprises at least one C═C bond, or at least one C≡C bond.

6. The resist composition of claim 4, wherein, Rx⁻ in Formula 1 above has a structure of CH₂=CH—CH═CHCOO⁻, CH₂=CH—CH₂—CH₂COO⁻, CH₃—CH₂—CH═CHCOO⁻, CH₂=CH—CH═CHSO₃⁻, CH₂=CH—CH₂—CH₂SO₃⁻ or CH₃—CH₂—CH═CHSO₃⁻.

7. A method for manufacturing a semiconductor device, comprising:
forming an etching target layer on a substrate;
forming a photoresist film on the etching target layer; and
performing an exposure process on the photoresist film,
wherein the exposure process is performed using EUV or electron beam,
the photoresist film includes a metal-oxo cluster having a counter anion,
the counter anion is a carboxylate anion having a substituted or unsubstituted unsaturated hydrocarbon group having 2 to 20 carbons, or a sulfonate anion having a substituted or unsubstituted unsaturated hydrocarbon group having 2 to 20 carbons.

8. The method of claim 7, wherein the metal-oxo cluster is represented by Formula 1:
[(R-M)₁₂O₁₄(OH)₆]²⁺[Rx⁻]₂ [Formula 1]
where, in Formula 1 above,
M is a metal and is at least one selected from the group consisting of tin (Sn), zinc (Zn), lithium (Li), sodium (Na), potassium (K), beryllium (Be), magnesium (Mg), calcium (Ca), barium (Ba), aluminum (Al), silicon (Si), cadmium (Cd), mercury (Hg), chromium (Cr), iron (Fe), cobalt (Co), nickel (Ni), copper (Cu), germanium (Ge), palladium (Pd), platinum (Pt), lead (Pb), strontium (Sr), and manganese (Mn),
R is an alkyl group having 1 to 20 carbons, or a halogenated alkyl group having 1 to 20 carbons, and
Rx⁻ is the counter anion.

9. The method of claim 8, wherein Rx⁻ in Formula 1 above has a structure of Formula 2 or Formula 3: 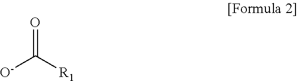
where, in Formula 2, R₁ is a substituted or unsubstituted unsaturated hydrocarbon group having 2 to 20 carbons that comprises at least one C═C bond, or at least one C≡C bond: 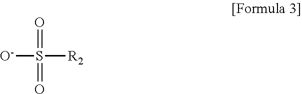
where, in Formula 3, R₂ is a substituted or unsubstituted unsaturated hydrocarbon group having 2 to 20 carbons that comprises at least one C═C bond, or at least one C≡C bond.

10. The method of claim 8,
wherein, in Formula 1 above, M is tin (Sn), and
R is an alkyl group having 1 to 20 carbons, or a fluoroalkyl group having 1 to 20 carbons.

11. The method of claim 7, wherein the photoresist film comprises:
a first portion exposed by the exposure process; and
a second portion unexposed by the exposure process, and
the first portion of the photoresist film comprises a structure in which the metal-oxo clusters are cross-linked to each other via the counter anion.

12. The method of claim 11, further comprising selectively removing the second portion of the photoresist film by performing the developing process.

13. A method for manufacturing a semiconductor device comprising:
forming an etching target layer on a substrate;
forming a photoresist film on the etching target layer; and
performing an exposure process on the photoresist film,
wherein, the photoresist film includes a metal-oxo cluster represented by Formula 1:
[(R-M)₁₂O₁₄(OH)₆]²⁺[Rx⁻]₂ [Formula 1]
where, in Formula 1 above,
M is a metal and is at least one selected from the group consisting of tin (Sn), zinc (Zn), lithium (Li), sodium (Na), potassium (K), beryllium (Be), magnesium (Mg), calcium (Ca), barium (Ba), aluminum (Al), silicon (Si), cadmium (Cd), mercury (Hg), chromium (Cr), iron (Fe), cobalt (Co), nickel (Ni), copper (Cu), germanium (Ge), palladium (Pd), platinum (Pt), lead (Pb), strontium (Sr), and manganese (Mn),
R is an alkyl group having 1 to 20 carbons, or a halogenated alkyl group having 1 to 20 carbons,
Rx⁻ is a counter anion and is a carboxylate anion having a substituted or unsubstituted unsaturated hydrocarbon group having 2 to 20 carbons, or a sulfonate anion having a substituted or unsubstituted unsaturated hydrocarbon group having 2 to 20 carbons.

14. The method of claim 13,
wherein, in Formula 1 above, M is tin (Sn), and
R is an alkyl group having 1 to 20 carbons, or a fluoroalkyl group having 1 to 20 carbons.

15. The method of claim 14, wherein, Rx⁻ in Formula 1 above has a structure of Formula 2 or Formula 3: 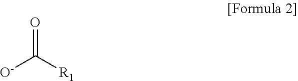
where, in Formula 2, R₁ is a substituted or unsubstituted unsaturated hydrocarbon group having 2 to 20 carbons that comprises at least one C═C bond, or at least one C≡C bond: 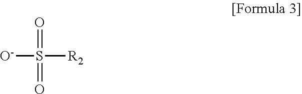
where, in Formula 2, R₂ is a substituted or unsubstituted unsaturated hydrocarbon group having 2 to 20 carbons that comprises at least one C═C bond, or at least one C≡C bond

16. The method of claim 13, wherein the exposure process is performed by using EUV or electron beam.

17. The method of claim 13, wherein the photoresist film comprises:
a first portion exposed by the exposure process; and
a second portion unexposed by the exposure process, and
the first portion of the photoresist film includes a structure in which the metal-oxo clusters represented by Formula 1 above are cross-linked to each other via the counter anion.

18. The method of claim 17, further comprising selectively removing the second portion of the photoresist film by performing a developing process.
